(19) United States
(12) Patent Application Publication
(10) Pub. No.: US 2012/0063237 A1
(43) Pub. Date: Mar. 15, 2012

(54) NONVOLATILE MEMORY DEVICE AND METHOD OF OPERATING THE SAME

(76) Inventor: Andrea GHILARDELLI, Cinisello Balsamo (IT)

(21) Appl. No.: 13/231,191

(22) Filed: Sep. 13, 2011

(30) Foreign Application Priority Data
Sep. 14, 2010 (KR) 10-2010-0089989

(51) Int. Cl. G11C 16/10

(52) U.S. Cl. 365/185.24

(57) ABSTRACT

A nonvolatile memory device includes a memory block including a plurality of memory cells grouped by word lines, an operation circuit group configured to perform a program operation or a read operation for the memory cells, and a control circuit configured to control the operation circuit group to set each of threshold voltages of a group of the memory cells, coupled to a word line selected from the word lines, to one of an erase level and five program levels in response to input data.

### CROSS-REFERENCE TO RELATED APPLICATION

Priority to Korean patent application number 10-2010-0089989 filed on Sep. 14, 2010, the entire disclosure of which is incorporated by reference herein, is claimed.

### BACKGROUND

Exemplary embodiments relate to a nonvolatile memory device and a method of operating the same and, more particularly, to a nonvolatile memory device and a method of operating the same, which store data of 2 bits or more in one memory cell.

In a nonvolatile memory device, the threshold voltages of memory cells each storing 1-bit data may have two voltage levels. That is, they have two distributional patterns. The threshold voltages of memory cells each storing 2-bit data have four distributional patterns. In order to increase the data storage capacity of nonvolatile memory devices, a method of storing 3-bit data in one memory cell has been proposed. In this case, the threshold voltages of the memory cells may have eight distributional patterns. It is, however, not easy to classify/distinguish the threshold voltages into the eight distributional patterns within a limited voltage range. In order to classify the threshold voltages into the eight distributional patterns, a sufficient margin is to be secured between the distribution patterns. If not, data stored in the memory cell may be sensed as a different value erroneously.

### BRIEF SUMMARY

An exemplary embodiment relates to an increase of the data storage capacity, as compared with the case where 2-bit data is stored in a memory cell.

Another exemplary embodiment relates to the increase of operational reliability by securing a sufficient margin between threshold voltage distribution patterns as compared with the case where 3-bit data is stored in a memory cell.

A nonvolatile memory device according to an aspect of the present disclosure includes a memory block including a plurality of memory cells grouped by word lines, an operation circuit group configured to perform a program operation or a read operation for the memory cells, and a control circuit configured to control the operation circuit group to set each of the threshold voltages of a group of the memory cells, coupled to a word line selected form the word lines, to one of an erase level and five program levels in response to input data.

A method of operating a nonvolatile memory device according to another aspect of the present disclosure includes performing a program loop for setting the threshold voltages of memory cells, coupled to a selected word line, to one of an erase level and five program levels in response to input data, and performing a read loop for sensing the threshold voltages of the memory cells and outputting 5-bit data for each pair of the memory cells using the sensed threshold voltages.

A method of operating a nonvolatile memory device according to further aspect of the present disclosure includes performing a first program loop for changing threshold voltages of memory cells coupled to a selected word line to store first and second bits of 5-bit data in each pair of the memory cells, performing a second program loop for changing the threshold voltages of the memory cells to store third and fourth bits of the 5-bit data in the each pair of the memory cells, and performing a third program loop for changing the threshold voltages of the memory cells to store a fifth bit of the 5-bit data in the each pair of the memory cells, wherein the threshold voltages of the memory cells are set to one of an erase voltage level and five program voltage levels

### BRIEF DESCRIPTION OF THE DRAWINGS

FIG. 1 is a block diagram of a nonvolatile memory device according to an exemplary embodiment of this disclosure;

FIG. 2 is a diagram illustrating a method of storing 5-bit data in each pair of memory cells.

FIG. 3 a diagram illustrating a method of representing 5-bit data based on the threshold voltages of a pair of memory cells;

FIGS. 4A to 4D show threshold voltage distributions illustrating the program loop and the read loop of memory cells; and

FIG. 5 is a diagram illustrating a program loop according to another exemplary embodiment of this disclosure.

### DESCRIPTION OF EMBODIMENTS

Hereinafter, some exemplary embodiments of the present disclosure will be described in detail with reference to the accompanying drawings. The figures are provided to enable those of ordinary skill in the art to make and use the embodiments of the disclosure.

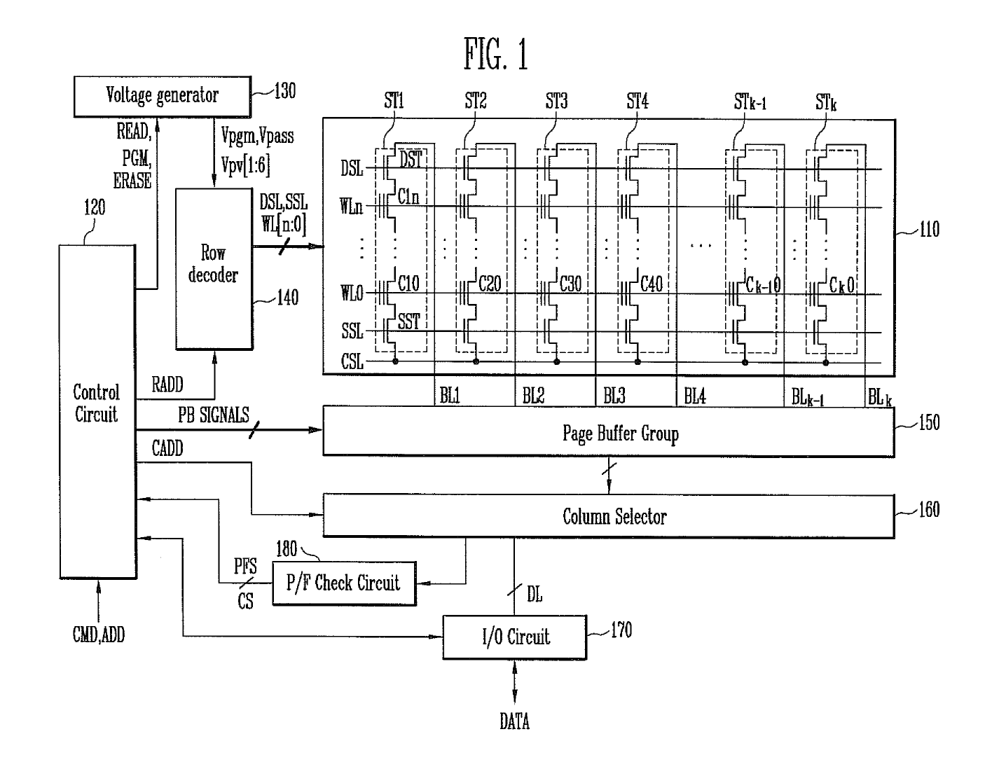

FIG. 1 is a block diagram of a nonvolatile memory device according to an exemplary embodiment of this disclosure.

Referring to FIG. 1, the nonvolatile memory device according to the exemplary embodiment of this disclosure includes a memory cell array 110, an operation circuit group (130, 140, 150, 160, 170, and 180) configured to perform a program operation or a read operation for memory cells included in the memory cell array 110, and a control circuit 120 configured to control the operation circuit group (130, 140, 150, 160, 170, and 180) in order to set the threshold voltages of selected memory cells to one of an erase level and five program levels based on received data.

Here, the nonvolatile memory device may be a NAND flash memory device. Further, the operation circuit group may include a voltage generator 130, a row decoder 140, a page buffer group 150, a column selector 160, an I/O circuit 170, and a pass/fail (P/F) check circuit 180.

The memory cell array 110 may include a plurality of memory blocks. For illustration purposes, FIG. 1 shows one of the memory blocks. The memory block includes a plurality of strings ST1 to STk. Each of the strings, e.g., the string ST1, includes a source select transistor SST coupled to a common source line CSL, a plurality of memory cells C10 to C1n, and a drain select transistor DST coupled to a bit line BL1. The gate of the source select transistor SST is coupled to a source select line SSL. The gates of the memory cells C10 to C1n are coupled to respective word lines WL0 to WLn. The gate of the drain select transistor DST is coupled to a drain select line DSL. The strings ST1 to STk are coupled to the respective bit lines BL1 to BLk and are commonly coupled to the common source line CSL.

In the NAND flash memory device, the memory blocks may be classified/distinguished on the basis of physical pages or logical pages. The page (e.g., an even page and an odd page) is the basic unit of a program operation or a read operation.

For example, the memory cells C10 to Ck0 coupled to one word line WL0 may form one physical page. Furthermore, the odd-numbered memory cells C10, C30 to Ck-10 coupled to one word line WL0 may form one odd physical page, and the even-numbered memory cells C20, C40 to Ck0 coupled to one word line WL0 may form one even physical page.

The number of logical pages included in each word line is determined by the number of bits of data stored in a memory cell of the word line. For example, if 2-bit data is stored in the memory cell, two logical pages are included in the word line. If 3-bit data is stored in the memory cell, three logical pages are included in the word line.

However, a 2.5 logical page cannot be included in one word line because data cannot be stored in a memory cell by a 0.5 bit. Accordingly, to store 2.5-bit data in a memory cell means to store 5-bit data in a pair of memory cells (for example, C10 and C20). In this case, a method of classifying logical pages is also to be changed. This will be described in detail later.

The control circuit 120 generates a program operation signal PGM, a read operation signal READ, or an erase operation signal ERASE in response to a command signal CMD and also generates control signals PB SIGNALS for controlling page buffers (not shown) of the page buffer group 150 based on a type of the operation. Furthermore, the control circuit 120 internally generates a row address signal RADD and a column address signal CADD in response to an address signal ADD. The control circuit 120 checks whether the threshold voltages of selected memory cells have risen to at least a target voltage based on a check signal PFS generated by the P/F check circuit 180 in a program verification operation and determines whether to perform a program operation again or to terminate the program operation based on a result of the check.

The voltage supply circuit (130, 140) supplies the drain select line DSL, the word lines WL0 to WLn, and the source select line SSL of a selected memory block with operating voltages for the program operation, the erase operation, and the read operation of memory cells in response to the signals READ, PGM, ERASE, and RADD of the control circuit 120. The voltage supply circuit includes the voltage generator 130 and the row decoder 140.

The voltage generator 130 outputs the operating voltages for programming, reading, and erasing selected memory cells to global lines in response to the signals PGM, READ, and ERASE and outputs operating voltages (for example, Vpgm, Vpass, and Vpv[1:6]) for a program to the global lines when memory cells are programmed.

The row decoder 140 transfers the operating voltages of the voltage generator 130 to the strings ST1 to STk of a memory block of the memory cell array 110 in response to the row address signals RADD of the control circuit 120. That is, the operating voltages are supplied to the local lines DSL, WL[0:n], and SSL of the memory block.

The page buffer group 150 includes the page buffers (not shown) coupled to the respective bit lines BL1 to BLk. The page buffer group 150 supplies the bit lines BL1 to BLk with respective voltages used to store data in the memory cells C10 to Ck0 in response to the control signals PB SIGNALS of the control circuit 120. More particularly, in the program operation, the erase operation, or the read operation of the memory cells C10 to Ck0, the page buffer group 150 precharges the bit lines BL1 to BLk or latches data corresponding to threshold voltages of the memory cells C10 to Ck0 which are detected based on a shift in the voltages of the bit lines BL1 to BLk. That is, the page buffer group 150 controls the voltages of the bit lines BL1 to BLk based on data stored in the memory cells C10 to Ck0 and detects data stored in the memory cells C10 to Ck0.

The column selector 160 selects the page buffers of the page buffer group 150 in response to the column address signal CADD of the control circuit 120 and outputs data latched in the selected page buffers.

The I/O circuit 170 transfers external data DATA to the column selector 160 under the control of the control circuit 120 during a program operation so that the data is inputted to the page buffer group 150. When the column selector 160 sequentially transfers the data to the page buffers of the page buffer group 150, the page buffers store the received data in their latches. Furthermore, when a read operation is performed, the I/O circuit 170 externally outputs data DATA received from the page buffers of the page buffer group 150 via the column selector 160.

The P/F check circuit 180 checks whether an error cell having a threshold voltage lower than a target voltage exists in programmed memory cells in a program verification operation performed after a program operation and outputs a result of the check as a check signal PFS. Furthermore, the P/F check circuit 180 counts the number of error cells and outputs a result of the count as a check signal CS.

The control circuit 120 controls the voltage generator 130 so that a program voltage can be supplied to a selected word line in the program operation of relevant memory cells and verification voltages Vpv[1:6] can be selectively supplied to the word line in a program verification operation. Furthermore, the control circuit 120 may control the voltage generator 130 in response to the check signal PFS of the P/F check circuit 180.

In particular, the control circuit 120 controls the operation circuit group (130, 140, 150, 160, 170, and 180) so as to perform a least significant bit (hereinafter referred to as an ‘LSB’) program loop for storing LSB data in memory cells, a most significant bit (hereinafter referred to as an ‘MSB’) program loop for storing MSB data in the memory cells, and a 1-bit program loop for storing 1-bit data in every pair of memory cells among the memory cells. After the LSB program loop, the MSB program loop, and the 1-bit program loop are performed, each of the threshold voltages of the memory cells is set to one of an erase level and five program levels based on input data.

Furthermore, the control circuit 120 controls the operation circuit group (130, 140, 150, 160, 170, and 180) such that the threshold voltages of memory cells are sensed and 5-bit data is outputted based on the sensed threshold voltages of each pair of the memory cells.

For example, the control circuit 120 may control the operation circuit group (130, 140, 150, 160, 170, and 180) so as to perform an LSB read loop for reading LSB data from memory cells, an MSB read loop for reading MSB data from the memory cells, and a 1-bit read loop for reading 1-bit data from each pair of memory cells of the memory cells.

A method of storing 5-bit data in a pair of memory cells in the semiconductor memory device is described as follows.

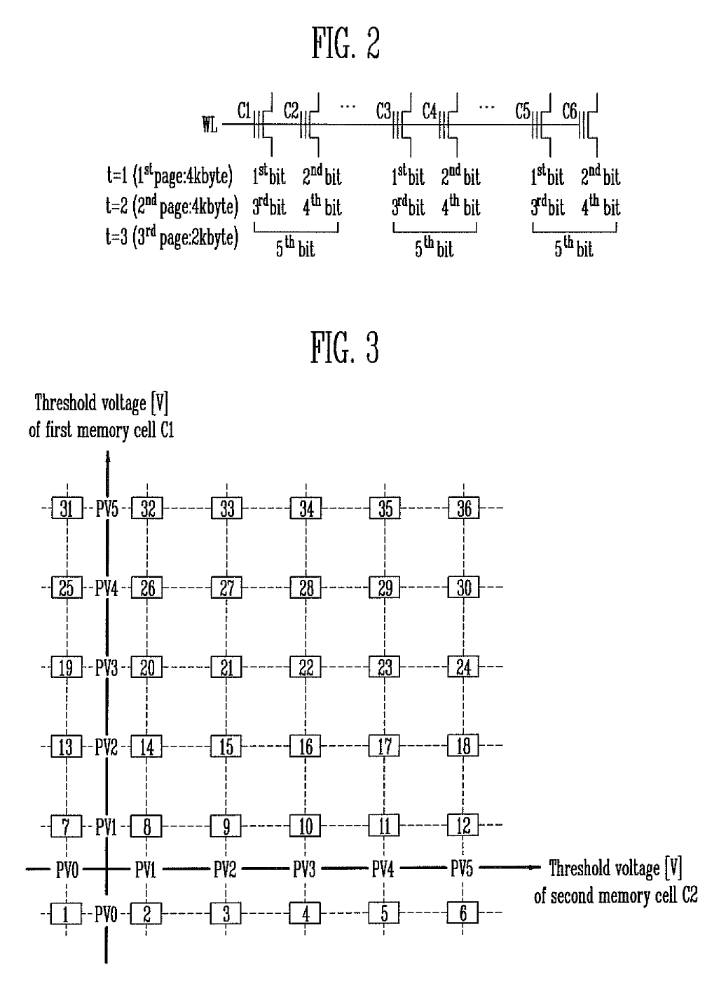

FIG. 2 is a diagram illustrating a method of storing 5-bit data in each pair of memory cells. FIG. 3 is a diagram illustrating a method of representing 5-bit data based on the threshold voltages of a pair of memory cells.

Referring to FIGS. 2 and 3, although 32768 memory cells corresponding to 4 k bytes may be coupled to one word line, 6 memory cells C1 to C6 coupled to the word line are shown, for the purpose of illustration. The control gates of the memory cells C1 to C6 are coupled to the word line WL.

In order to store 2-bit data in each memory cell, the threshold voltages of the memory cells may be classified into 4(2²) levels. In order to store 3-bit data in each memory cell, the threshold voltages of the memory cells may be classified into 8(2³) levels. If the threshold voltages of the memory cells are classified into an erase level PV0 and first to fifth program levels PV1 to PV5 based on data stored in the memory cells, the threshold voltages of a pair of memory cells C1 and C2 can represent 36(6×6) different cases. Thus, 5-bit data using the 32(2⁵) classified levels of the threshold voltages can be stored in the pair of memory cells. That is, 2.5-bit data may be averagely stored in one memory cell. The remaining four cases of the threshold voltages other than those used to store the 5-bit data may be used for other purposes or may not be used.

For example, data stored in the first and the second memory cells C1 and C2 may be classified as one of data ‘00000’ to ‘11111’ based on the 32 cases in which the threshold voltage of the first memory cell C1 has the first to sixth level PV0 to PV5 while the threshold voltage of the second memory cell C2 has the first to second levels PV0 to PV1.

In order to store 2-bit data in one memory cell, 2 logical pages are included in one word line. In order to store 3-bit data in one memory cell, 3 logical pages are included in one word line.

In order to store 5-bit data in a pair of memory cells, 3 logical pages may be included. For example, a first page (that is, LSB page) for storing LSB data in the memory cells C1 to C6, a second page (that is, MSB page) for storing MSB data, and a third page (that is, 1-bit page) for further storing 1-bit data in each pair of memory cells may be used.

The data storage capacity of each of the first and the second pages is 4 k bytes in the embodiment shown in FIG. 2. However, since 1-bit data is stored in each pair of memory cells in the third page, the data storage capacity of the third page is 2 k bytes.

Each of the threshold voltages of the memory cells C1 to C6 coupled to the word line is set to one of the erase level PV0 and the five program levels PV1 to PV5 based on received data by means of a program loop. Furthermore, 5-bit data is outputted using threshold voltages read from each pair of the memory cells by means of a read loop.

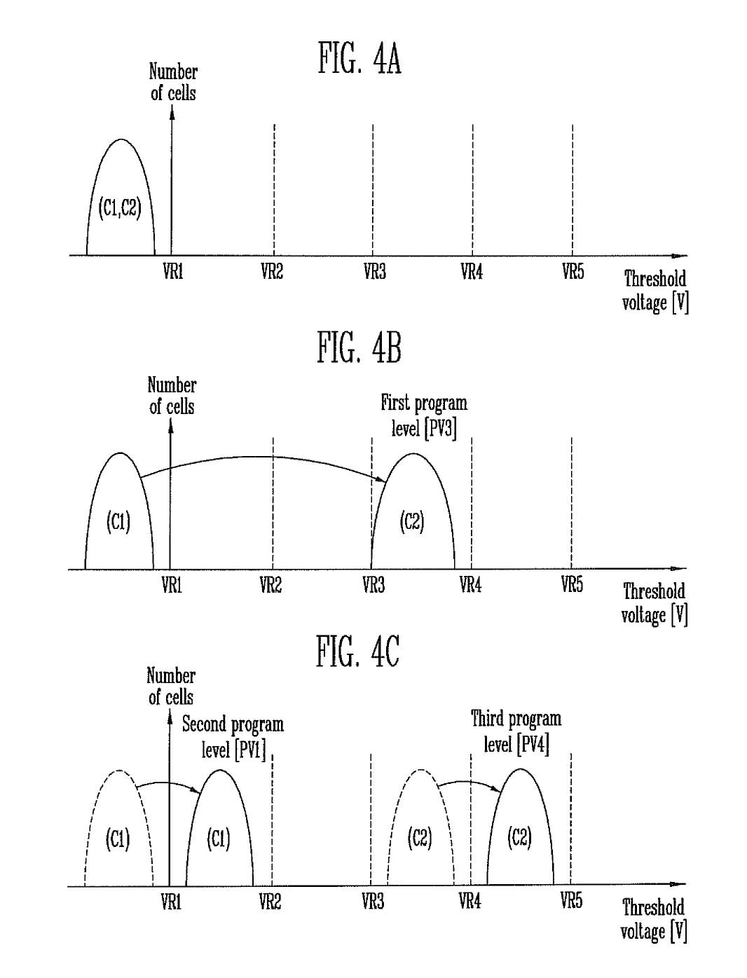

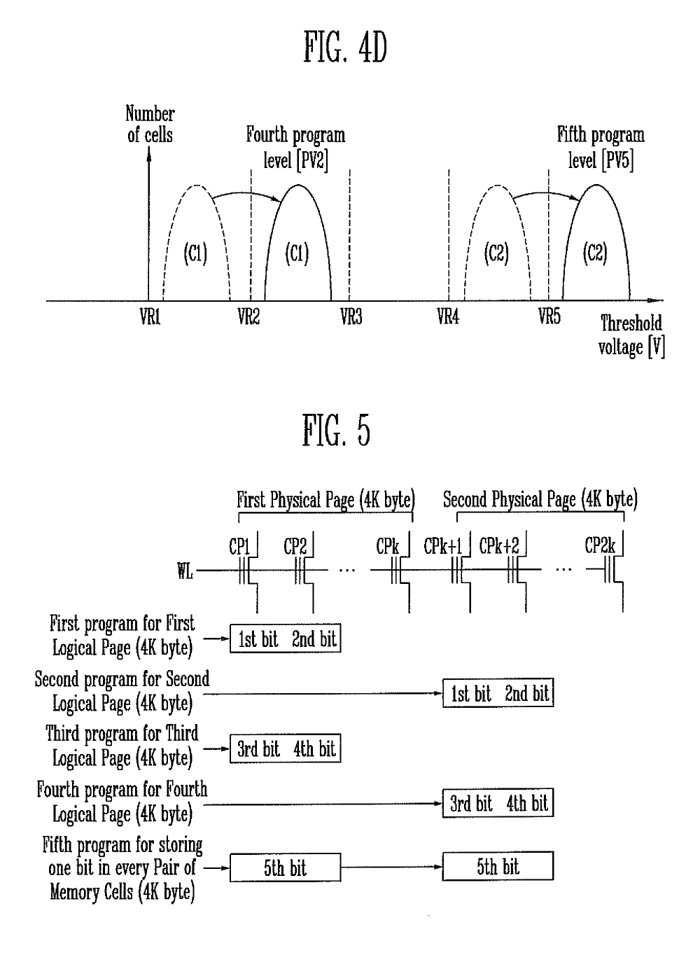

FIGS. 4A to 4D show threshold voltage distributions illustrating the program loop and the read loop of memory cells.

First, a process in which the threshold voltages of a pair of memory cells C1 and C2 shift by means of a program loop for storing 5-bit data in the pair of memory cells is described as follows. The shift process of the threshold voltages to be described hereinafter may be likewise applied to the memory cells C3 and C4 (or, C5 and C6), but the threshold voltages of the memory cells set based on stored data may be changed.

Referring to FIGS. 2, 3, and 4A, the threshold voltages of the memory cells C1 and C2 are initially set to the erase level PV0 lower than 0 V. In this case, it may be considered that data ‘00000’ is stored in the pair of memory cells C1 and C2.

Referring to FIGS. 2, 3, and 4B, in order to store 1-bit data (that is, LSB data) in the memory cells C1 to C6, a first program loop (that is, LSB program loop) is performed. The threshold voltage of the second memory cell C2, selected from among the memory cells C1 and C2, rises up to the first program level PV3 based on the LSB data by means of the first program loop. In this case, it may be considered that data ‘00011’ is stored in the pair of memory cells C1 and C2. The data ‘00011’ may correspond to the fourth case/combination of threshold voltages. That is, when storing the data ‘00011’ in the pair of memory cells C1 and C2, the threshold voltage of the first memory cell C1 maintains the erase level PV0, and the threshold voltage of the second memory cell C2 is raised up to the first program level PV3 by means of the first program loop.

The first program loop is performed by the operation circuit group under the control of the control circuit 120. The first program loop includes a program operation and a program verification operation. The program operation and the program verification operation of a nonvolatile memory device are known in the art, and a detailed description thereof is omitted.

Referring to FIGS. 2 and 4C, in order to store 1-bit data (that is, MSB data) in the memory cells C1 to C6, a second program loop (that is, MSB program loop) is performed. The threshold voltage of the first memory cell C1 of the memory cells C1 and C2 rises up to the second program level PV1 based on the MSB data by means of the second program loop. Furthermore, the threshold voltage of the second memory cell C2 rises up to the third program level PV4 higher than the first program level PV3 by means of the second program loop.

In this case, it may be considered that data ‘01010’ corresponding to the eleventh case is stored in the pair of memory cells C1 and C2. That is, when storing the data ‘01010’ in the pair of memory cells C1 and C2, the threshold voltage of the first memory cell C1 is raised up to the second program level PV1, and the threshold voltage of the second memory cell C2 is raised up to the third program level PV4.

Referring to FIGS. 2 and 4D, in order to further store third data (that is, 1-bit data) in the pair of memory cells C1 to C6, a third program loop (that is, 1-bit program loop) is performed. The threshold voltage of the first memory cell C1 rises up to the fourth program level PV2 and the threshold voltage of the second memory cell C2 rises up to the fifth program level PV5, based on the further stored 1-bit data.

In this case, it may be considered that data ‘10001’ corresponding to the eighteenth case is stored in the pair of memory cells C1 and C2. That is, when storing the data ‘10001’ in the pair of memory cells C1 and C2, the threshold voltage of the first memory cell C1 is raised up to the fourth program level PV2, and the threshold voltage of the second memory cell C2 is raised up to the fifth program level PV5.

The method of setting the threshold voltages of memory cells may be changed according to stored data type or the circuit design. Furthermore, not only the LSB data and the MSB data, but also the 1-bit data are stored in the pair of first and second memory cells C1 and C2. Accordingly, the threshold voltages of the first and the second memory cells C1 and C2 may be set to different levels owing to the further stored 1-bit data even when they store the same LSB data and the same MSB data.

A read loop for outputting 5-bit data stored in a pair of memory cells is described as follows.

The read loop includes an LSB read loop for reading LSB data from the memory cells, an MSB read loop for reading MSB data from the memory cells, and a 1-bit read loop for reading 1-bit data from each pair of memory cells.

For example, in a first read loop corresponding to the LSB read loop, LSB data corresponding to first 1-bit data and LSB data corresponding to second 1-bit data are read from a pair of memory cells by supplying a first read voltage VR3 to a word line coupled to the memory cells. In a second read loop corresponding to the MSB read loop, MSB data corresponding to third 1-bit data and MSB data corresponding to fourth 1-bit data are read from the pair of memory cells by sequentially supplying second and third read voltages VR1 and VR4 to the word line. Furthermore, in a third read loop corresponding to the 1-bit read loop, the threshold voltages of a pair of the memory cells are sensed by sequentially supplying fourth and fifth read voltages VR2 and VR5 to the word line. The sensed threshold voltages are combined and then outputted in the form of fifth 1-bit data. Accordingly, 5-bit data is outputted from the pair of memory cells. The read loop of the nonvolatile memory device is known in the art, and a detailed description thereof is omitted.

Referring to FIG. 2, each of the first page (that is, LSB page) and the second page (that is, MSB page) has the data storage capacity of 4 k bytes. However, in the third page, the 1-bit data is further stored in a pair of memory cells. Accordingly, the third page has the data storage capacity of 2 k bytes. If the data storage capacities of the pages are different as described above, it may be difficult to set an address for selecting a page. Therefore, by increasing the number of memory cells coupled to each word line, plural (e.g. two) physical pages may be included in each word line. In an alternative embodiment, a program loop may be performed by dividing memory cells, coupled to a word line, into two groups (or two physical pages) irrespective of the number of memory cells coupled to the word line. This program loop is described as follows.

FIG. 5 is a diagram illustrating a program loop according to another exemplary embodiment of this disclosure.

Referring to FIG. 5, memory cells coupled to a selected word line are divided into first and second memory groups (or first and second physical pages). Therefore, the number of memory cells coupled to each word line may be doubled, and thus 65536 (=8×1024×8) memory cells corresponding to 8 k bytes may be coupled to each word line. Although the number of memory cells coupled to the word line is increased, the data storage capacity of each of the first and the second physical pages is 4 k bytes the same as in FIG. 2. However, the number of logical pages included in the word line becomes 5.

For example, two logical pages (that is, a LSB logical page and a MSB logical page) may be included in the first physical page of the word line, and two logical pages (that is, a LSB logical page and a MSB logical page) may be included in the second physical page of the word line. Furthermore, a fifth logical page for storing 1-bit data in each pair of memory cells is further included in the whole first and the second physical pages. Consequently, the 2 physical pages and the 5 logical pages are included in one word line.

The program loop according to another exemplary embodiment of this disclosure is described as follows.

Memory cells CP1 to CP2k coupled to a selected word line are divided into first and second memory groups (that is, first and second physical pages).

A first program loop (that is, a first LSB program loop) is performed in order to store LSB data (that is, 1-bit program data) in the memory cells CP1 to CPk included in the first physical page. In the first physical page, the threshold voltages of each pair of the memory cells are shifted based on the first program bit data and the second program bit data stored therein, owing to the first program loop.

In this case, for example, the method described with reference to FIGS. 2 and 4B may be used. That is, the threshold voltages of first to third memory cells of the memory cells CP1 to CPk, included in the first physical page, may be raised up to the first program level PV3 by means of the first program loop.

A second program loop (that is, a second LSB program loop) is performed in order to store the LSB data (that is, 1-bit program data) in the memory cells CPk+1 to CP2k of the second physical page. In the second physical page, the threshold voltages of each pair of the memory cells are shifted based on the first program bit data and the second program bit data stored therein, owing the second program loop.

In this case, for example, the method described with reference to FIGS. 2 and 4B may be used. That is, the threshold voltages of first to third memory cells of the memory cells CPk+1 to CP2k, included in the second memory group, may be raised up to the first program level PV3 by means of the second program loop.

A third program loop (that is, a first MSB program loop) is performed in order to store MSB data (that is, 1-bit program data) in the memory cells CP1 to CPk of the first physical page. Accordingly, in the first physical page, the 1-bit program data is further stored in each of the memory cells CP1 to CPk. The threshold voltages of each pair of the memory cells included in the first physical page are shifted based on the third and the fourth program bit data stored therein by means of the third program loop.

In this case, for example, the method described with reference to FIGS. 2 and 4C may be used. That is, the threshold voltages of fourth and fifth memory cells of the memory cells CP1 to CPk, included in the first memory group, are raised up to the second program level PV1 lower than the first program level PV3 and the threshold voltages of second and third memory cells of the memory cells CP1 to CPk are raised up to the third program level PV4 higher than the first program level PV3, by means of the third program loop.

A fourth program loop (that is, a second MSB program loop) is performed in order to store the MSB data (that is, 1-bit program data) in the memory cells CPk+1 to CP2k of the second physical page. Accordingly, in the second physical page, the third and the fourth program bit data is further stored in the each pair of memory cells CPk+1 and CPk+2. In the second physical page, the threshold voltages of the memory cells CPk+1 to CP2k are shifted based on the further stored 1-bit program data by means of the fourth program loop.

In this case, for example, the method as described with reference to FIGS. 2 and 4C may be used. That is, the threshold voltages of fourth and fifth memory cells of the memory cells CPk+1 to CP2k, included in the second memory group, may be raised up to the second program level PV1 lower than the first program level PV3 and the threshold voltages of second and third memory cells of the memory cells CPk+1 to CP2k may be raised up to the third program level PV4 higher than the first program level PV3 by means of the fourth program loop.

Furthermore, a fifth program loop (that is, a 1-bit program loop) is performed in order to further store 1-bit data in each pair of the memory cells CP1 to CP2k of the first and the second physical pages. The data storage capacity of the first and the second physical pages is 8K bytes. However, since the 1-bit data is stored in each pair of memory cells, a fifth logical page has a data storage capacity of 4K bytes and has the same capacitance as other logical pages.

The threshold voltages of the memory cells CP1 to CP2k included in the first and the second physical pages are shifted based on the further stored 1-bit program data by means of the fifth program loop.

In this case, for example, the method described with reference to FIGS. 2 and 4D may be used. That is, the threshold voltage of a fifth memory cell of the memory cells CP1 to CP2k, included in the first and the second memory groups, may be raised up to the fourth program level PV2 between the second and the first program levels PV1 and PV3 and the threshold voltage of a third memory cell of the memory cells CP1 to CP2k may be raised up to the fifth program level PV5 higher than the third program level PV4, by means of the fifth program loop.

The threshold voltages of the remaining memory cells maintain the erase level.

When memory cells coupled to a word line are divided into two or more physical pages and program loops are performed as described above, logical pages can be set to have the same data storage capacity.

After the program operation is completed as described above, a read operation is performed as follows.

Like in the sequence of the program operation, the first LSB data stored in the first logical page, i.e., the memory cells CP1 to CPk included in the first physical page, is outputted. The second LSB data stored in the second logical page, i.e., the memory cells CPk+1 to CP2k included in the second physical page, is outputted. Next, the first MSB data stored in the third logical page, i.e., the memory cells CP1 to CPk included in the first physical page, is outputted. The second MSB data stored in the fourth logical page i.e., the memory cells CPk+1 to CP2k included in the second physical page, is outputted. Next, the data stored in the fifth logical page is outputted from each pair of memory cells included in the first and the second physical pages.

Through the above operation, the data outputted from the logical pages has the same capacity.

According to the exemplary embodiments of this disclosure, 5-bit data is stored in each pair of memory cells. Accordingly, the data storage capacity can be increased, as compared with the case where 2-bit data is stored in a memory cell. Furthermore, operational reliability can be increased by securing a sufficient margin between threshold voltage distributions as compared with the case where 3-bit data is stored in a memory cell.

What is claimed is:

1. A nonvolatile memory device, comprising:
a memory block comprising a plurality of memory cells grouped by word lines;
an operation circuit group configured to perform a program operation or a read operation for the memory cells; and
a control circuit configured to control the operation circuit group to set each of threshold voltages of a group of the memory cells, coupled to a word line selected from the word lines, to one of an erase level and five program levels in response to input data.

2. The nonvolatile memory device of claim 1, wherein the operation circuit group is configured to perform a least significant bit (LSB) program loop for storing LSB data in the group of the memory cells, a most significant bit (MSB) program loop for storing MSB data in the group of the memory cells, and a 1-bit program loop for storing 1-bit data in each pair of the group of the memory cells under control of the control circuit,
wherein the each of the threshold voltages of the group of the memory cells is set to one of the erase level and the five program levels after the LSB program loop, the MSB program loop, and the 1-bit program loop are performed.

3. The nonvolatile memory device of claim 1, wherein the control circuit controls the operation circuit to sense the threshold voltages of the groups of the memory cells and output 5-bit data for each pair of the group of the memory cells based on the sensed threshold voltages.

4. The nonvolatile memory device of claim 3, wherein the operation circuit group is configured to perform a least significant bit (LSB) read loop for reading LSB data from the group of the memory cells, a most significant bit (MSB) read loop for reading MSB data from the group of the memory cells, and a 1-bit read loop for reading 1-bit data from the each pair of the groups of the memory cells under control of the control circuit.

5. A method of operating a nonvolatile memory device, comprising:
performing a program loop for setting threshold voltages of memory cells, coupled to a selected word line, to one of an erase level and five program levels in response to input data; and
performing a read loop for sensing the threshold voltages of the memory cells and outputting 5-bit data for each pair of the memory cells using the sensed threshold voltages.

6. The method of claim 5, wherein the program loop comprises:
a least significant bit (LSB) program loop for storing LSB data in the memory cells;
a most significant bit (MSB) program loop for storing MSB data in the memory cells; and
a 1-bit program loop for storing 1-bit data in the each pair of the memory cells.

7. The method of claim 5, wherein the program loop comprises:
a first program loop for changing threshold voltage levels of a selected one of the memory cells based on first 1-bit data to be stored in each of the memory cells;
a second program loop for changing threshold voltage levels of a selected one of the memory cells based on second 1-bit data to be further stored in the each of the memory cells; and
a third program loop for changing threshold voltage levels of the memory cells based on third 1-bit data to be further stored in the each pair of the memory cells.

8. The method of claim 5, wherein the program loop comprises:
a first program loop for raising threshold voltages of first to third memory cells of the memory cells to a first program level;
a second program loop for raising threshold voltages of fourth and fifth memory cells of the memory cells to a second program level lower than the first program level and raising the threshold voltages of the second and the third memory cells to a third program level higher than the first program level; and
a third program loop for raising the threshold voltage of the fifth memory cell of the memory cells to a fourth program level between the second and the first program levels and raising the threshold voltage of the third memory cell to a fifth program level higher than the third program level,
wherein the threshold voltages of the remaining memory cells are set to the erase level.

9. The method of claim 5, wherein the memory cells of the word line are divided into first and second memory groups,
wherein the program loop comprises:
a first least significant bit (LSB) program loop for storing first LSB data in the memory cells of the first memory group;
a second LSB program loop for storing second LSB data in the memory cells of the second memory group;
a first most significant bit (MSB) program loop for storing first MSB data in the memory cells of the first memory group;
a second MSB program loop for storing second MSB data in the memory cells of the second memory group; and
a 1-bit program loop for storing 1-bit data in each pair of the memory cells of the first and the second memory groups.

10. The method of claim 5, wherein the memory cells of the word line are divided into first and second memory groups,
wherein the program loop comprises:
a first program loop for changing threshold voltage levels of a selected one of the memory cells of the first memory group based on first 1-bit data to be stored in each of the memory cells of the first memory group;
a second program loop changing threshold voltage levels of a selected one of the memory cells of the second memory group based on second 1-bit data to be stored in the each of the memory cells of the second memory group;
a third program loop for changing threshold voltage levels of a selected one of the memory cells of the first memory group based on third 1-bit data to be further stored in the each of the memory cells of the first memory group;
a fourth program loop for changing threshold voltage levels of a selected one of the memory cells of the second memory group based on fourth 1-bit data to be further stored in the each of the memory cells of the second memory group; and
a fifth program loop for changing threshold voltage levels of a selected one of the memory cells of the first and the second memory groups based on fifth 1-bit data to be further stored in the each pair of the memory cells.

11. The method of claim 5, wherein the memory cells of the word line are divided into first and second memory groups,
wherein the program loop comprises:
a first program loop for raising threshold voltages of first to third memory cells of the memory cells of the first memory group to a first program level;
a second program loop for raising threshold voltages of first to third memory cells of the memory cells of the second memory group to the first program level;
a third program loop for raising threshold voltages of fourth and fifth memory cells of the memory cells of the first memory group to a second program level lower than the first program level and raising the threshold voltages of the second and the third memory cells to a third program level higher than the first program level;
a fourth program loop for raising threshold voltages of fourth and fifth memory cells of the memory cells of the second memory group to the second program level lower than the first program level and raising the threshold voltages of the second and the third memory cells to the third program level higher than the first program level; and
a fifth program loop for raising the threshold voltages of the fifth memory cells of the first and the second memory groups to a fourth program level between the second and the first program levels and raising the threshold voltages of the third memory cells of the first and the second memory groups to a fifth program level higher than the third program level,
wherein the threshold voltages of the remaining memory cells are set to the erase level.

12. The method of claim 5, wherein the read loop comprises:
a least significant bit (LSB) read loop for reading LSB data from the memory cells;
a most significant bit (MSB) read loop for reading MSB data from the memory cells; and
a 1-bit read loop for reading 1-bit data from the each pair of the memory cells.

13. The method of claim 5, wherein the read loop comprises:
a first read loop for outputting first 1-bit data and second 1-bit data from the each pair of the memory cells by supplying a first read voltage to the word line;
a second read loop for outputting third 1-bit data and fourth 1-bit data from the each pair of the memory cells by supplying second and third read voltages to the word line; and
a third read loop for sensing the threshold voltages of the each pair of the memory cells by supplying fourth and fifth read voltages to the word line and outputting fifth 1-bit data by combining the sensed threshold voltages.

14. A method of operating a nonvolatile memory device, comprising:
performing a first program loop for changing threshold voltages of memory cells coupled to a selected word line to store first and second bits of 5-bit data in each pair of the memory cells;
performing a second program loop for changing the threshold voltages of the memory cells to store third and fourth bits of the 5-bit data in the each pair of the memory cells; and
performing a third program loop for changing the threshold voltages of the memory cells to store a fifth bit of the 5-bit data in the each pair of the memory cells,
wherein the threshold voltages of the memory cells are set to one of an erase voltage level and five program voltage levels.

15. The method of claim 14, further comprising:
sensing the threshold voltages of the memory cells by supplying read voltages to the word lines; and
outputting the 5-bit data for each pair of the memory cells by combining the sensed threshold voltages.
